(19) United States
(12) Patent Application Publication
(10) Pub. No.: US 2011/0304412 A1
(43) Pub. Date: Dec. 15, 2011

(54) Acoustic Wave Resonators and Methods of Manufacturing Same

(76) Inventor: Hao Zhang, Zhuhai (CN)

(21) Appl. No.: 12/813,147

(22) Filed: Jun. 10, 2010

(51) Int. Cl. H03H 9/54; H01L 41/22

(52) U.S. Cl. 333/187; 29/25.35

(57) ABSTRACT

In one aspect of the invention, the acoustic wave resonator includes a substrate defined an air cavity, a first passivation layer formed on the substrate and over the air cavity, a seed layer formed on the passivation layer, a bottom electrode formed on the seed layer, a piezoelectric layer formed on the bottom electrode, a top electrode formed on the piezoelectric layer, and a second passivation layer formed on the top electrode.

### CROSS-REFERENCE TO RELATED PATENT APPLICATION

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference were individually incorporated by reference.

### FIELD OF THE INVENTION

The present invention relates generally to an acoustic wave resonator, and more particular to an acoustic wave resonator having one or more passivation layers and methods of manufacturing same.

### BACKGROUND OF THE INVENTION

A simple construction of the thin film bulk acoustic wave (BAW) resonator is composed of opposed planar electrodes and a piezoelectric element between the electrodes. In operation, an electric field, which varies with time, is induced in the piezoelectric layer by applying electric energy to the electrodes. This electric field causes a bulk acoustic wave to be generated in a vibrating direction of the piezoelectric layer, thereby generating resonance. The acoustic wave propagates in the same direction as the electric field, and reflects at the boundary of electrodes. A BAW resonator is conventionally fabricated on the surface of the substrate by depositing the bottom electrode, the piezoelectric film, and then the top electrode. Therefore, a top air/electrode interface exists and only the bottom interface requires some design selections. To allow the BAW resonator to resonate mechanically in response to an electrical signal applied between the electrodes, there are two known approaches for obtaining the desired characteristics at the bottom interface and the fundamental difference between the two approaches is the means by which the acoustic energy is trapped. The first approach is to suspend resonator membrane (hereinafter referred to as “FBAR”) over an air cavity defined in a substrate. One method involves etching away the substrate material from the back side of the substrate. If the substrate is silicon, a portion of the substrate beneath resonator stack is removed using back side bulk silicon etching. Most commonly, the back side bulk silicon etching can be done either using deep trench reactive ion etching or using a crystallographic orientation dependent etch, such as KOH, TMAH, and EDP. In another configuration, the device structure is suspended over a shallow cavity in or on the substrate. Typically, a sacrificial layer is deposited and the acoustic resonator layer stack is then fabricated on top of the sacrificial layer. At or near the end of the process, the sacrificial layer is removed. The second approach is to provide a proper acoustic reflector in place of the air/layer interface as described above, the resonator (referred to as “SMR”) is solidly mounted on top of a stack of layers of alternating high and low acoustic impedance materials which effectively trap acoustic energy in the piezoelectric layer. This addition of an acoustic reflector degrades the effective coupling coefficient of SMR as well as creating additional energy loss mechanisms that results in overall worse Q factor of SMR than that of FBAR.

As packaging cost can contribute considerably to overall fabrication cost, packaging FBAR or SMR devices in a cost effective way is a key for their commercial success in consumer markets. Because there is no bottom air cavity, passivation of SMR and the related packaging is easier than air gap type FBAR that usually requires hermetic packaging. The non-hermetic approach is lower in cost but may require perfectly passivated resonators which do not corrode in a humid environment.

Therefore, a heretofore unaddressed need exists in the art to address the aforementioned deficiencies and inadequacies.

### SUMMARY OF THE INVENTION

One of the objectives of the invention is to provide an FBAR that eliminates or alleviates susceptibility of the FBAR from frequency drifts due to interaction with its environment such as air or moisture and substantially relax the packaging hermeticity requirements, while maintaining its high performance in both of the electromechanical coupling coefficient and quality factor.

In one aspect, the present invention relates to an acoustic wave resonator. In one embodiment, the acoustic wave resonator has a substrate defining an air cavity; a first passivation layer formed on the substrate and located over the air cavity; a seed layer formed on the first passivation layer such that the first passivation layer protects the seed layer from reaction with an environment surrounding the resonator; a multilayered structure formed on the seed layer; and a second passivation layer formed on the top surface of the multilayered structure.

In one embodiment, the multilayered structure has a bottom electrode formed on the seed layer; a piezoelectric layer formed on the bottom electrode; and a top electrode formed on the piezoelectric layer.

In another embodiment, the multilayered structure has a first bottom electrode formed on the seed layer; a first piezoelectric layer formed on the first bottom electrode; a first top electrode formed on the first piezoelectric layer; a decoupling layer formed on the first top electrode; a second bottom electrode formed on the decoupling layer; a second piezoelectric layer formed on the second bottom electrode; and a second top electrode formed on the second piezoelectric layer.

The first passivation layer comprises a material of silicon carbide, aluminum oxide, diamond, diamond-like carbon (DLC), silicon oxide, silicon nitride, hydrophobic polymer or a combination thereof. The second passivation layer comprises a material that is different from or identical to the material of the first passivation layer. The seed layer comprises a material of aluminum nitride, aluminum oxynitride, tungsten nitride, titanium tungsten nitride, silicon oxide, silicon nitride, silicon carbide, or a combination thereof.

In one embodiment, the first passivation layer has a thickness ranging from 10 Angstroms to 10,000 Angstroms.

In another aspect, the present invention relates to a method for manufacturing an acoustic wave resonator. In one embodiment, the method includes the steps of providing a substrate with a sacrificial layer; forming a first passivation layer on the sacrificial layer extending over the substrate layer; forming a seed layer on the first passivation layer; forming a multilayered structure; forming a second passivation layer on the top surface of the multilayered structure; and removing the sacrificial layer from the substrate to form an air cavity.

In one embodiment, the step of forming the multilayered structure comprises the steps of forming a bottom electrode on the seed layer; forming a piezoelectric layer on the bottom electrode; and forming a top electrode on the piezoelectric layer.

In another embodiment, the step of forming the multilayered structure comprises the steps of forming a first bottom electrode on the seed layer; forming a first piezoelectric layer on the first bottom electrode; forming a first top electrode on the first piezoelectric layer; forming a decoupling layer on the first top electrode; forming a second bottom electrode on the decoupling layer; forming a second piezoelectric layer on the second bottom electrode; and forming a second top electrode on the second piezoelectric layer.

In one embodiment, the first passivation layer is formed of a material of silicon carbide, aluminum oxide, diamond, diamond-like carbon (DLC), silicon oxide, silicon nitride, hydrophobic polymer and a combination thereof. The second passivation layer is formed of a material that is different from or identical to the material of the first passivation layer.

In one embodiment, the first passivation layer has a thickness ranging from 10 Angstroms to 10,000 Angstroms.

In one embodiment, the seed layer is formed of a material of aluminum nitride, aluminum oxynitride, tungsten nitride, titanium tungsten nitride, silicon oxide, silicon nitride, silicon carbide, or a combination thereof.

In yet another aspect, the present invention relates to a method for manufacturing an acoustic wave resonator. In one embodiment, the method includes the steps of providing a substrate; forming a first passivation layer on the substrate; forming a seed layer on the first passivation layer; forming a multilayered structure; forming a second passivation layer on the top surface of the multilayered structure; and removing a portion of the substrate on which the first passivation layer is formed to form an air cavity therein.

In one embodiment, the step of forming the multilayered structure comprises the steps of forming a bottom electrode on the seed layer; forming a piezoelectric layer on the bottom electrode; and forming a top electrode on the piezoelectric layer.

In another embodiment, the step of forming the multilayered structure comprises the steps of forming a first bottom electrode on the seed layer; forming a first piezoelectric layer on the first bottom electrode; forming a first top electrode on the first piezoelectric layer; forming a decoupling layer on the first top electrode; forming a second bottom electrode on the decoupling layer; forming a second piezoelectric layer on the second bottom electrode; and forming a second top electrode on the second piezoelectric layer.

In one embodiment, the first passivation layer is formed of a material of silicon carbide, aluminum oxide, diamond, diamond-like carbon (DLC), silicon oxide, silicon nitride, hydrophobic polymer and a combination thereof. Preferably, the first passivation layer has a thickness ranging from 10 Angstroms to 10,000 Angstroms. The second passivation layer is formed of a material that is different from or identical to the material of the first passivation layer.

In one embodiment, the seed layer is formed of a material of aluminum nitride, aluminum oxynitride, tungsten nitride, titanium tungsten nitride, silicon oxide, silicon nitride, silicon carbide, or a combination thereof.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIGS. 1A and 1B show cross sectional views of an acoustic wave resonator according to a first embodiment of the present invention;

FIGS. 2A and 2B show cross sectional views of an acoustic wave resonator according to a second embodiment of the present invention;

FIGS. 3A and 3B show cross sectional views of an acoustic wave resonator according to a third embodiment of the present invention;

FIGS. 4A and 4B show cross sectional views of an acoustic wave resonator according to a fourth embodiment of the present invention;

FIG. 5 shows a flowchart of manufacturing the acoustic wave resonator shown in FIGS. 1A and 1B;

FIG. 6 shows a flowchart of manufacturing the acoustic wave resonator shown in FIGS. 2A and 2B;

FIG. 7 shows a flowchart of manufacturing the acoustic wave resonator shown in

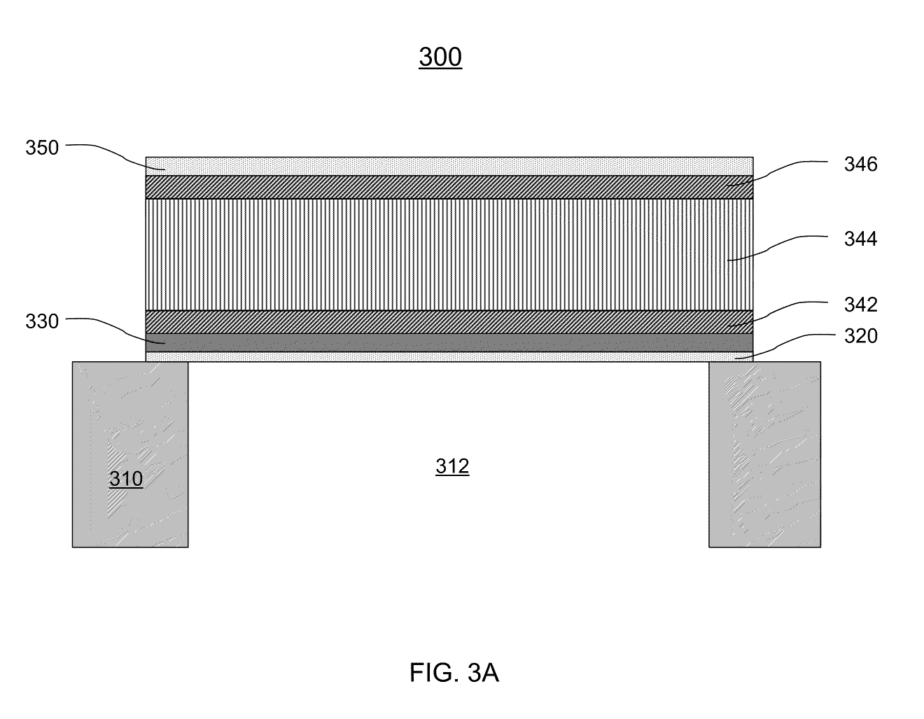

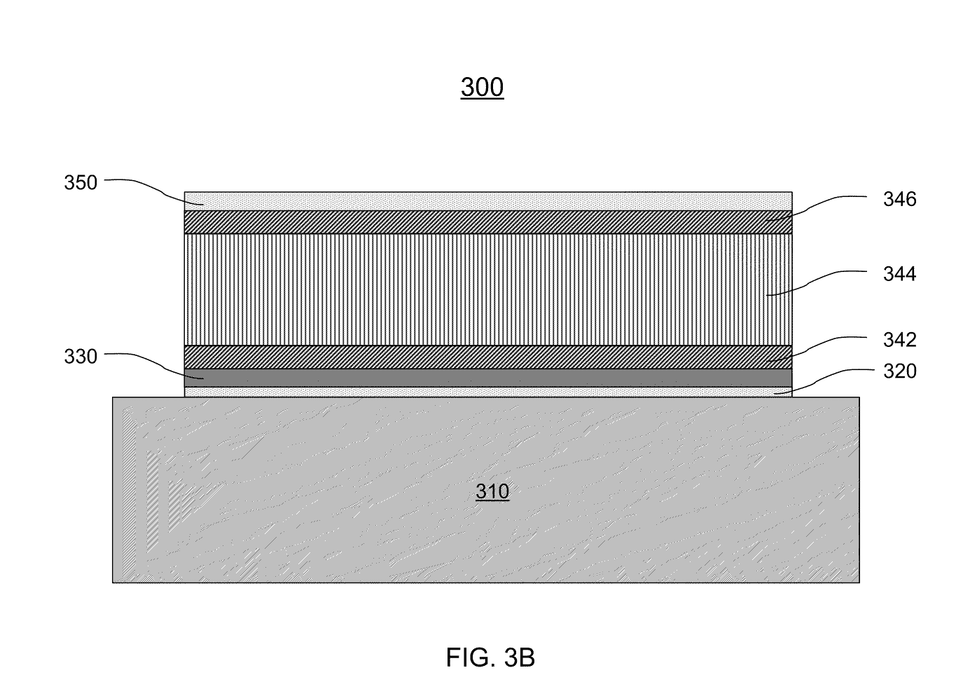

FIGS. 3A and 3B; and

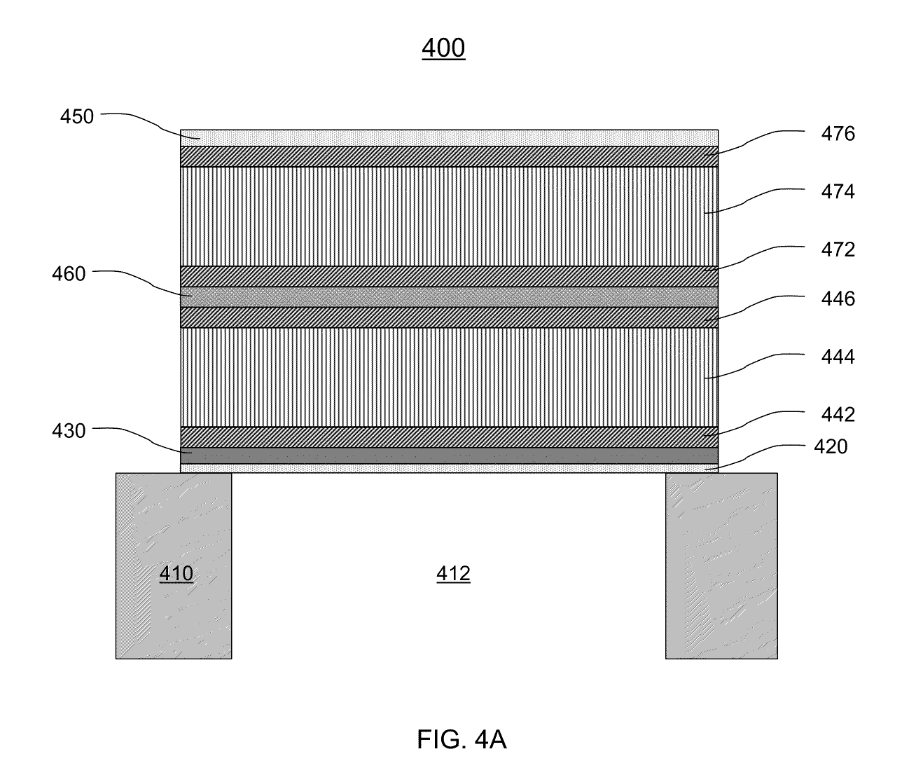

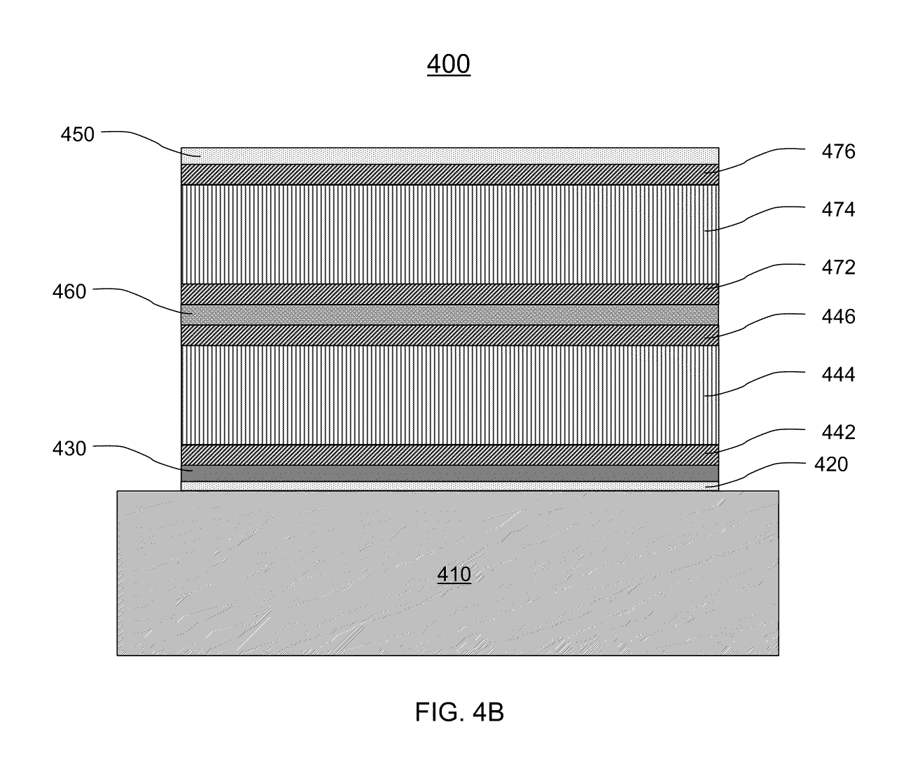

FIG. 8 shows a flowchart of manufacturing the acoustic wave resonator shown in FIGS. 4A and 4B.

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The term “layer”, as used herein, refers to a thin sheet or thin film.

The term “environment”, as used herein, refers to a space outside a resonator, encompasses air, moisture or contamination.

The term “electrode”, as used herein, is an electrically conductive layer or film comprising a single-layer structure or a multi-layer structure formed of one or more electrically conductive materials.

The term “piezoelectric layer” as used herein, is a layer comprising one or more different layers, of which at least one exhibits piezoelectric activity. The other layers may be non-piezoelectric dielectric or used to perform special performance effects like temperature coefficient compensation or to facilitate manufacturing like adhesion layers. In addition, the other layers are typically thin when compared to the at least one layer exhibiting piezoelectric activity.

As used herein, the terms “fabricating process”, “fabricating method”, “manufacturing process”, or “manufacturing method” are exchangeable, and refer to a process or method of making or producing an article or device, such as bulk acoustic wave resonator, i.e., FBAR.

Embodiments in the present invention relates to methods for manufacturing acoustic wave devices. An example of the acoustic wave devices, FBAR is described in following embodiments.

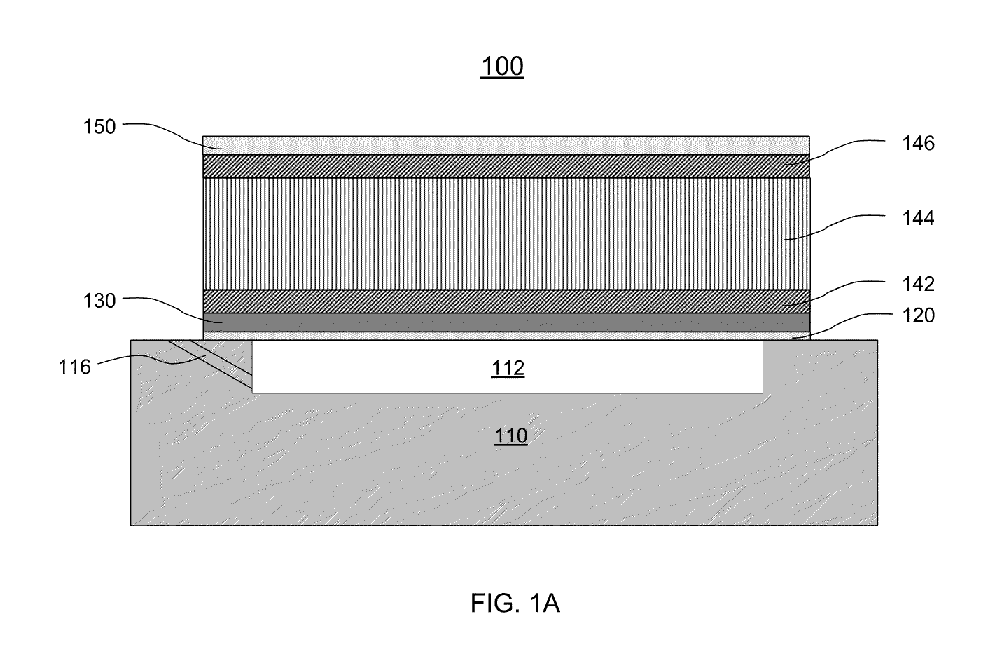

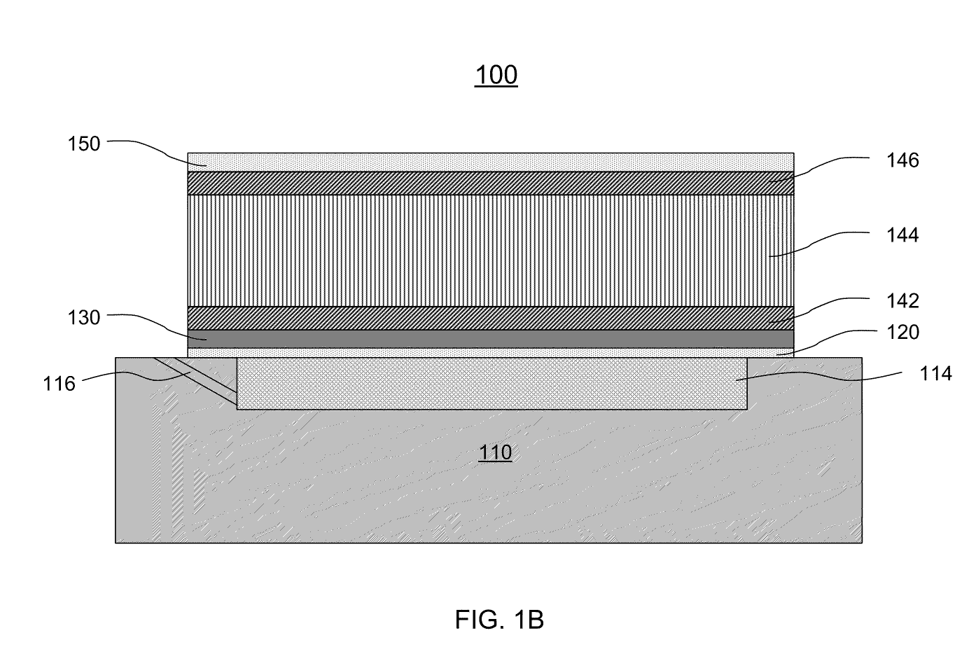

The description will be made as to the embodiments of the present invention in conjunction with the accompanying drawings of FIGS. 1-8. In accordance with the purposes of this invention, as embodied and broadly described herein, this invention, in one aspect, relates to an acoustic wave resonator, fabricated on a substrate with an air cavity, having a first passivation layer, a seed layer, a bottom electrode, a piezoelectric portion, a top electrode and a second passivation layer stacked in series. The seed layer is formed of a selected material so as to cause the grain of the bottom electrode to orient properly, which is necessary for growing a highly textured piezoelectric layer. The first passivation layer is adapted for reducing the tendency of a material absorbed on the surface of the resonator structure and serves as a protective underlayer protecting the seed layer from reaction with air and possible moisture from the environment reaching the seed layer via an air cavity, which is a hole left after the sacrificial layer released. Accordingly, the resonant frequency drifting caused by environment contaminants is minimized and the resonator is protected from detrimental effects caused by humidity or corrosive fluids.

Referring to FIGS. 1A and 1B, a resonator 100 is shown according to the first embodiment of the present invention. The resonator 100 includes a substrate 110, a first passivation layer 120 formed on the substrate 110, a seed layer 130 formed on the first passivation layer 120, a bottom electrode 142 formed on the seed layer 130, a piezoelectric layer 144 formed on the bottom electrode 142, a top electrode 146 formed on the piezoelectric layer 144 and a second passivation layer 150 formed on the top electrode 146.

The substrate 110 has an air cavity 112. The air cavity 112 is formed on a top surface of the substrate 110 or in the substrate 110. Optionally, the air cavity 112 is filled with a sacrificial layer 114 first. The sacrificial layer 114 is removed at or near the end of the fabricating process by an etching process, such as dry plasma and wet chemical etching, or other appropriate processes. In one embodiment, the sacrificial layer 114 is etched via an evacuation tunnel 116, which communicates the air cavity 112 with an environment outside the resonator 100 so as to define the air cavity 112 therein. The sacrificial layer 114 can also be removed by an etching process from the backside of the substrate 110 to form the air cavity 112 therein.

The first passivation layer 120 is directly formed on the substrate 110 and over the air cavity 112. Preferably, the first passivation layer 120 has a thickness ranging from about 10 Angstroms to 10,000 Angstroms.

The seed layer 130 is formed on the first passivation layer 120. The seed layer 130 is formed of a material of aluminum nitride (AlN), aluminum oxynitride (AlON), tungsten nitride (WN), titanium tungsten nitride (TiWN), silicon oxide (SiO₂), silicon nitride (Si₃N₄), silicon carbide (SiC), or the like. The seed layer 130 has a thickness that may range from about 10 Angstroms to about 10,000 Angstroms.

The first passivation layer 120 serves as a protective underlayer for protecting the seed layer 130 from reaction with air, possible moisture or contamination from the environment. Without the first passivation layer 120, the resonant frequency of the resonator 100 is more susceptible to drifting over time. Because the air cavity 112 communicates with the environment outside the resonator via the evacuation tunnel 116, the air, possible moisture or contamination from the environment may cause the exposure portion of the resonator oxidized. To reduce or minimize the resonant frequency-drifting problem, the first passivation layer 120 is typically an inert material less prone to reaction with the environment and made of a material of silicon carbide, aluminum oxide, diamond, diamond-like carbon (DLC), silicon oxide, silicon nitride, hydrophobic polymer, or the like.

Above the seed layer 130, the bottom electrode 142, the piezoelectric layer 144 and the top electrode 146 are deposited in sequence. The bottom electrode 142 and the top electrode 146 are formed of, for example, but not limited to, gold (Au), tungsten (W), molybdenum (Mo), platinum (Pt), ruthenium (Ru), iridium (Ir), titanium tungsten (TiW), aluminum (Al), or titanium (Ti). The piezoelectric layer 144 is formed of, for example, but not limited to, aluminum nitride (AlN), zinc oxide (ZnO), lead zirconate titantate (PZT), quartz, lithium niobate (LiNbO₃), potassium niobate (KNbO₃), or lithium tantalate (LiTaO₃).

It is known that the texture of the piezoelectric films is strongly dependent on both the roughness and the texture of the underlying electrode upon which it is deposited. The seed layer 130 provides a smoother, well-textured bottom electrode 142 which, in turn, promotes a highly textured c-axis piezoelectric layer 144 and results in an improved quality (e.g., higher piezoelectric coupling constant) of the piezoelectric layer 144, thus leading to a higher quality resonator 100. In one embodiment, the material of the seed layer 130 is identical to that of the piezoelectric layer 144, for example, AlN. The improved electromechanical coupling allows for wider bandwidth electrical filters to be built with the resonator 100.

Further, the second passivation layer 150 is deposited on the top electrode 146 with a material that is different from or identical to the material of the first passivation layer 120. The second passivation layer 150 is used to protect the top electrode 146 from exposing to air, moisture or contaminant so as to stabilize the performance of the resonator 100.

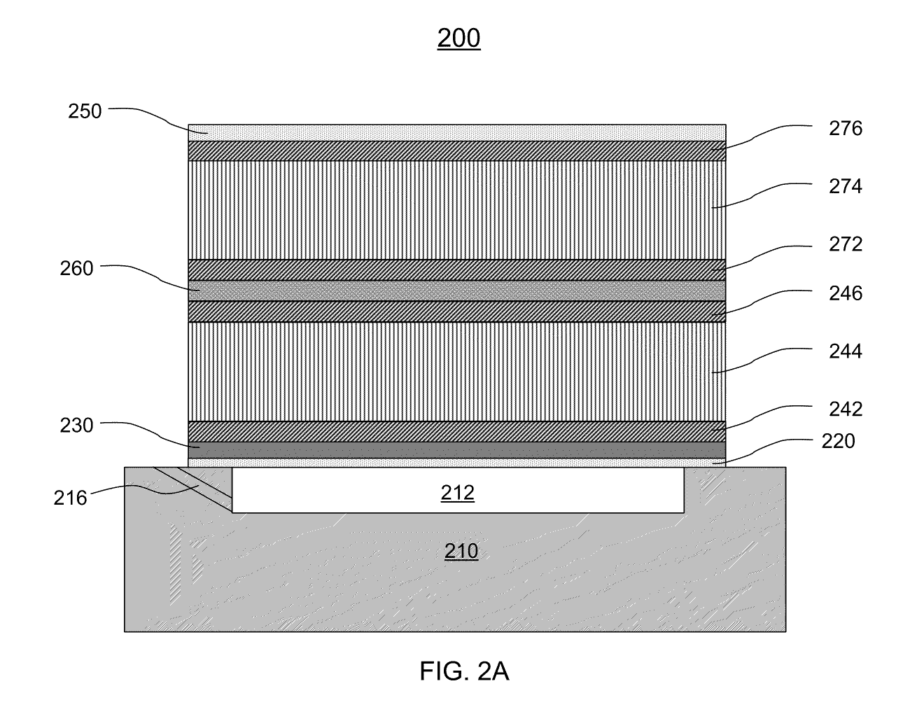

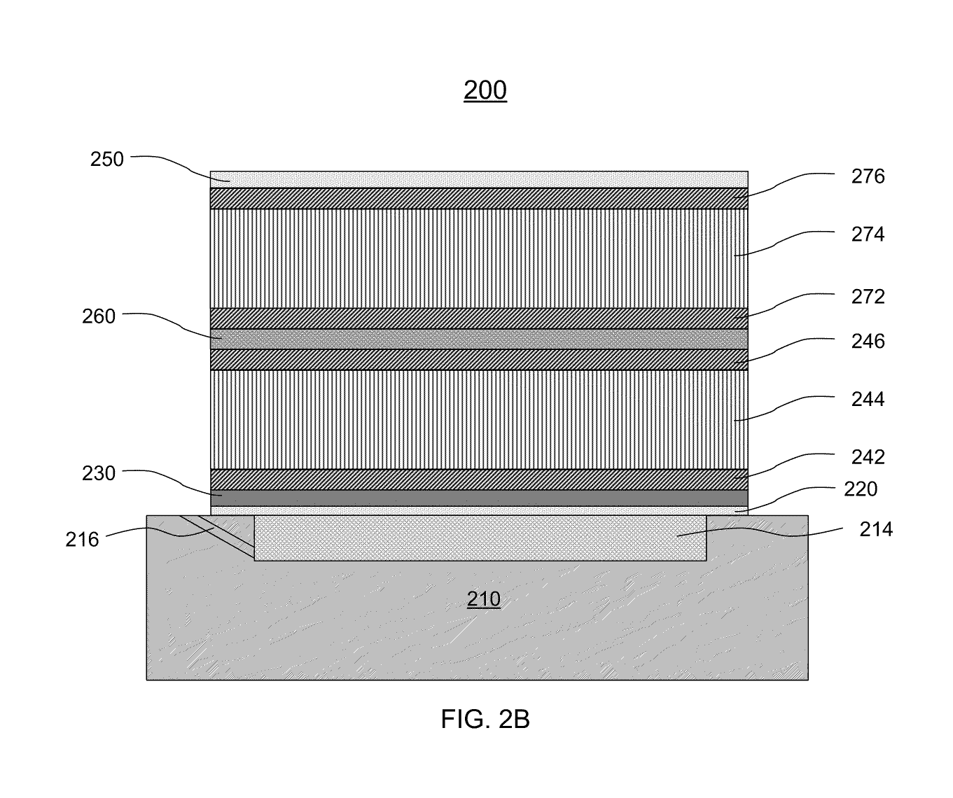

Referring to FIGS. 2A and 2B, a resonator 200 is shown according to the second embodiment of the present invention. The resonator 200 includes a substrate 210, a first passivation layer 220 formed on the substrate 210, a seed layer 230 formed on the first passivation layer 220, a first bottom electrode 242 formed on the seed layer 230, a first piezoelectric layer 244 formed on the first bottom electrode 242, a first top electrode 246 formed on the first piezoelectric layer 244, a decoupling layer 260 formed on the first top electrode 246, a second bottom electrode 272 formed on the decoupling layer 260, a second piezoelectric layer 274 formed on the second bottom electrode 272, a second top electrode 276 formed on the second piezoelectric layer 274, and a second passivation layer 250 is formed on the second top electrode 276.

The substrate 210 includes an air cavity 212 formed on a top surface of the substrate 210 or in the substrate 210. The air cavity 212 may be filled with a sacrificial layer 214. The sacrificial layer 214 may be removed at or near the end of the fabricating process by an etching process, such as dry plasma and wet chemical etching, or other appropriate processes. The sacrificial layer 214 is etched via an evacuation tunnel 216, which communicates the air cavity 212 with an environment outside the resonator 200 to form the air cavity 212 therein. Other removing processes such as deep reactive ion etching (DRIE) and crystallographic orientation dependent wet etching by KOH, TMAH, or EDP can be utilized to remove the sacrificial layer 214 from the substrate 210.

The first passivation layer 220 is directly formed over the air cavity 212. Preferably, the first passivation layer 220 has a thickness ranging from about 10 Angstroms to about 10,000 Angstroms.

The seed layer 230 is formed on the first passivation layer 220. The seed layer 230 is formed of a material of AlN, AlON, WN, TiWN, SiO₂, Si₃N₄, SiC or the like. The seed layer 230 has a thickness that may range from about 10 Angstroms to about 10,000 Angstroms.

The first passivation layer 220 serves as a protective underlayer protecting the seed layer 230 from reaction with air, possible moisture or contamination from the environment. Without the first passivation layer 220, the resonant frequency of the resonator 200 is more susceptible to drifting over time. Because the air cavity 212 communicates with the environment outside the resonator via the evacuation tunnel 216, the air, possible moisture or contamination from the environment may cause the exposure portion of the resonator oxidize. To reduce or minimize the resonant frequency-drifting problem, the first passivation layer 220 is typically an inert material less prone to reaction with the environment and made of a material of silicon carbide, aluminum oxide, diamond, diamond-like carbon (DLC), silicon oxide, silicon nitride, or hydrophobic polymer or their combination.

The first bottom electrode 242, the first piezoelectric layer 244, the first top electrode 246 are stacked sequentially on the seed layer 230 to form a first FBAR. The second bottom electrode 272, the second piezoelectric layer 274, and the second top electrode 276 are stacked sequentially to form a second FBAR. The first and second FBARs are stacked vertically to constitute a CRF. Such a CRF can achieve higher rejection at the far stop-band and wider bandwidth.

The first bottom electrode 242, the first top electrode 246, the second bottom electrode 272, the second top electrode 276 are formed of, for example, but not limited to, Au, W, Mo, Pt, Ru, Ir, TiW, Al, or Ti. The first piezoelectric layer 244 and the second piezoelectric layer 274 are formed of, for example, but not limited to, AlN, ZnO, PZT, quartz, LiNbO₃, KNbO₃, or LiTaO₃.

The decoupling layer 260 is sandwiched between the first top electrode 246 and the second bottom electrode 272. The decoupling layer 260 includes a single layer or a multilayer.

The seed layer 230 provides a smoother, well-textured underlying electrode on which the piezoelectric layer 244 can be fabricated. Accordingly, with the seed layer 230, a higher quality piezoelectric layer 244 can be fabricated, thus leading to a higher quality resonator 200. In one embodiment, the material used for the seed layer 230 and the piezoelectric layer 244 are the same material, for example, AlN.

Preferably, the second passivation layer 250 is formed on the second top electrode 276, so as to protect the second top electrode 276 from exposure to the air or moisture. The second passivation layer 250 is formed of a material that is different from or identical to the material of the first passivation layer 220.

Referring to FIGS. 3A and 3B, a resonator 300 is shown according to the third embodiment of the present invention. The resonator 300 includes a substrate 310, a first passivation layer 320 formed on the substrate 310, a seed layer 330 formed on the first passivation layer 320, a bottom electrode 342 formed on the seed layer 330, a piezoelectric layer 344 formed on the bottom electrode 342, a top electrode 346 formed on the piezoelectric layer 344, and a second passivation layer 350 formed on the top electrode 346. A portion of the substrate 310 on which the first passivation layer 320 is formed is removed by an etching process from the backside of the substrate 310 to form an air cavity 312 therein.

The first passivation layer 320 is directly formed over the air cavity 312. Preferably, the first passivation layer 320 has a thickness ranging from about 10 Angstroms to about 10,000 Angstroms.

The first passivation layer 320 serves as a protective underlayer protecting the seed layer 330 from reaction with air, possible moisture or contamination from the environment. Without the first passivation layer 320, the resonant frequency of the resonator 300 is more susceptible to drifting over time. Because the air cavity 312 communicates with the environment outside the resonator, the air, possible moisture or contamination from the environment may cause the exposure portion of the resonator oxidized. To reduce or minimize the resonant frequency-drifting problem, the first passivation layer 320 is typically an inert material less prone to reaction with the environment and made of a material of silicon carbide, aluminum oxide, diamond, diamond-like carbon (DLC), silicon oxide, silicon nitride, or hydrophobic polymer or their combination.

The seed layer 330 is directly formed on the first passivation layer 320. The seed layer 330 is formed of a material of AlN, AlON, WN, TiWN, SiO₂, Si₃N₄, or SiC or their combination.

Above the seed layer 330, the first bottom electrode 342, the piezoelectric layer 344 and the first top electrode 346 are deposited in sequence. The first bottom electrode 342 and the first top electrode 346 are made of, for example, but not limited to, Au, W, Mo, Pt, Ru, Ir, TiW, Al, or Ti. The piezoelectric layer 344 is formed of, for example, but not limited to, AlN, ZnO, PZT, quartz, LiNbO₃, KNbO₃, or LiTaO₃.

The seed layer 330 provides a smoother, well-textured underlying electrode on which the piezoelectric layer 344 can be fabricated. Accordingly, with the seed layer 330, a higher quality piezoelectric layer 344 can be fabricated, thus leading to a higher quality resonator 300. In one embodiment, the material used for the seed layer 330 and the piezoelectric layer 344 are the same material, for example, AlN.

The second passivation layer 350 is deposited on the top electrode 346. The second passivation layer 350 is used to protect the top electrode 346 from exposure to air, moisture or contaminant so as to stabilize the performance of the resonator 300. The second passivation layer 350 is formed of a material that is different from or identical to the material of the first passivation layer 320.

Referring to FIG. 4A and FIG. 4B, a resonator 400 is shown according to the fourth embodiment of the present invention. The resonator 400 includes a substrate 410, a first passivation layer 420, a seed layer 430, a first bottom electrode 442, a first piezoelectric layer 444, a first top electrode 446, a decoupling layer 460, a second bottom electrode 472, a second piezoelectric layer 474, a second top electrode 476, and a second passivation layer 450. A portion of the substrate 410 on which the first passivation layer 420 is formed is removed by an etching process from the backside of the substrate 410 to form an air cavity 412 therein.

The first passivation layer 420 is directly formed over the air cavity 412. Preferably, the first passivation layer 420 has a thickness ranging from about 10 Angstroms to about 10,000 Angstroms.

The seed layer 430 is formed on the first passivation layer 420. The seed layer 430 is formed of a material of AlN, AlON, WN, TiWN, SiO₂, Si₃N₄, or SiC or their combination.

The first passivation layer 420 serves as a protective underlayer protecting the seed layer 430 from reaction with air, possible moisture or contamination from the environment. Without the first passivation layer 420, the resonant frequency of the resonator 400 is more susceptible to drifting over time. Because the air cavity 412 communicates with the environment outside the resonator, the air, possible moisture or contamination from the environment may cause the exposure portion of the resonator oxidized. To reduce or minimize the resonant frequency-drifting problem, the first passivation layer 420 is typically an inert material less prone to reaction with the environment and made of a material of silicon carbide, aluminum oxide, diamond, diamond-like carbon (DLC), silicon oxide, silicon nitride, or hydrophobic polymer or their combination.

The first bottom electrode 442, the first piezoelectric layer 444, the first top electrode 446 are stacked sequentially on the first passivation layer 420 form a first FBAR. The second bottom electrode 472, the second piezoelectric layer 474, and the second top electrode 476 are stacked sequentially form a second FBAR. The first and second FBARs are stacked vertically to form a CRF. The CRF can achieve higher rejection at the far stop-band and wider bandwidth.

The first bottom electrode 442, the first top electrode 446, the second bottom electrode 472, the second top electrode 476 are formed of, for example, but not limited to, Au, W, Mo, Pt, Ru, Ir, TiW, Al, or Ti. The first piezoelectric layer 444 and the second piezoelectric layer 474 are formed of, for example, but not limited to, AlN, ZnO, PZT, quartz, LiNbO₃, KNbO₃, or LiTaO₃.

The decoupling layer 460 is sandwiched between the first top electrode 446 and the second bottom electrode 472. The decoupling layer 460 comprises a single layer or a multilayer.

The seed layer 430 provides a smoother, well-textured underlying electrode on which the piezoelectric layer 444 can be fabricated. Accordingly, with the seed layer 430, a higher quality piezoelectric layer 444 can be fabricated, thus leading to a higher quality resonator 400. In one embodiment, the material used for the seed layer 430 and the piezoelectric layer 444 are the same material, for example, AlN.

The second passivation layer 450 is formed on the second top electrode 476, so as to protect the second top electrode 476 from exposure to the air or moisture. The second passivation layer 450 is formed of a material that is different from or identical to the material of the first passivation layer 420.

The present invention also provides methods for manufacturing the acoustic wave resonators described above.

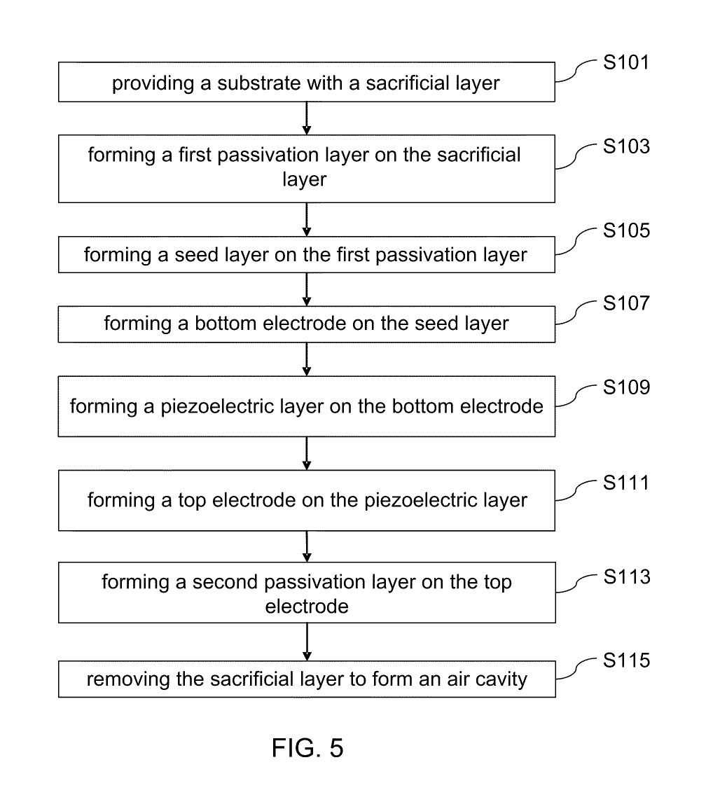

Referring to FIG. 5, accompanying with FIGS. 1A and 1B, a manufacturing flowchart of an acoustic wave resonator is shown according to one embodiment of the present invention, which includes the following steps.

At step S101, a substrate 110 with a sacrificial layer 114 is provided. The sacrificial material including silicon oxide, polysilicon, metal (e.g., germanium, magnesium, aluminum, etc), or polymer is deposited in the substrate 110 or on the top surface of the substrate 110, using a sputtering process, a CVD process, a PVD process, spin coating, or other appropriate processes. Then, the substrate 110 and sacrificial layer 114 are planarized.

At step S103, a first passivation layer 120 is formed on the substrate 110 and located over the sacrificial layer 114. Typically, the first passivation layer 120 is sputtered on the surface of substrate 110 and the sacrificial layer 114.

At step S105, a seed layer 130 is formed on the first passivation layer 120.

At step S107, a bottom electrode 142 is formed on the seed layer 130.

At step S109, a piezoelectric layer 144 is formed on the bottom electrode 142.

At step S111, a top electrode 146 is formed on the piezoelectric layer 144.

At step S113, a second passivation layer 150 is formed on the top electrode 146.

At step S115, the sacrificial layer 114 is then removed to form an air cavity 112. In one embodiment, the sacrificial layer 114 is etched via an evacuation tunnel 116. The evacuation tunnel 116 communicates the air cavity 112 with an environment outside the acoustic wave resonator 100. Other removing processes such as deep reactive ion etching (DRIE) and crystallographic orientation dependent wet etching by KOH, TMAH, or EDP can be utilized to remove the sacrificial layer 114 from the substrate 110. The step S115 can be performed prior to the step S107, step S109, step S111 or step S113. That is to say, the sacrificial layer 114 could be removed before the bottom electrode 142, the piezoelectric layer 144, the top electrode 146 or the second passivation layer 150 is formed.

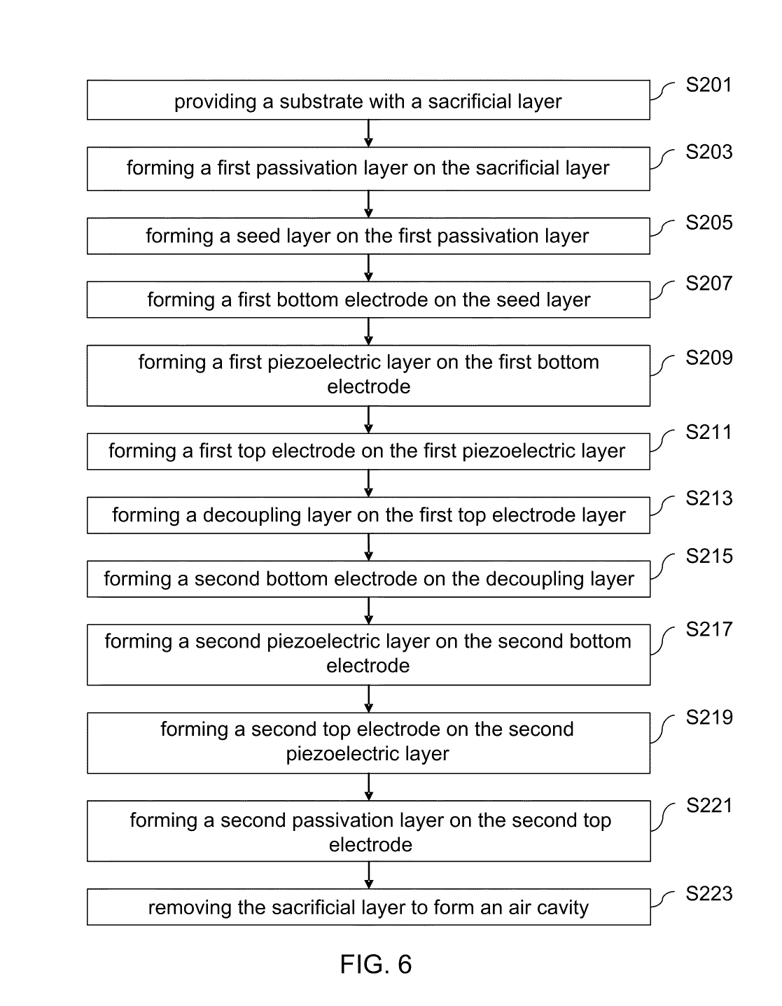

Referring to FIG. 6, accompanying with FIGS. 2A and 2B, a manufacturing flowchart of an acoustic wave resonator is shown according to another embodiment of the present invention. The manufacturing process includes the following steps.

At step S201, a substrate 210 with a sacrificial layer 214 is provided. The sacrificial material including silicon oxide, polysilicon, metal (e.g., germanium, magnesium, aluminum, etc), or polymer is deposited in the substrate 210 or on the top surface of the substrate 210, using a sputtering process, a CVD process, a PVD process, spin coating, or other appropriate processed. The, the substrate 210 and the sacrificial layer 214 are planarized.

At step S203, a first passivation layer 220 is formed on the sacrificial layer 214. Typically, the first passivation layer 220 is sputtered on the surface of substrate 210 and sacrificial layer 214.

At step S205, a seed layer 230 is formed on the first passivation layer 220.

At step S207, a first bottom electrode 242 is formed on the seed layer 230.

At step S209, a first piezoelectric layer 244 is formed on the first bottom electrode 242.

At step S211, a first top electrode 246 is formed on the first piezoelectric layer 244.

At step S213, a decoupling layer 260 is formed on first top electrode 246.

At step S215, a second bottom electrode 272 is formed on the decoupling layer 260.

At step S217, a second piezoelectric layer 274 is formed on the second bottom electrode 272.

At step S219, a second top electrode 276 is formed on the second piezoelectric layer 274.

At step S221, a second passivation layer 250 is formed on the second top electrode 276.

At step S223, the sacrificial layer 214 is then removed to form an air cavity 212.

In one embodiment, the sacrificial layer 214 is etched via a evacuation tunnel 216. The evacuation tunnel 216 communicates the air cavity 212 with an environment outside the acoustic wave resonator 200. Other removing processes such as deep reactive ion etching (DRIE) and crystallographic orientation dependent wet etching by KOH, TMAH, or EDP can be utilized to remove the sacrificial layer 214 from the substrate 210. The step S223 can be performed prior to the step S207, S209, S211, S213, S215, S217, S219 or S221. That is to say, the sacrificial layer 214 could be removed before the first bottom electrode 242, the first piezoelectric layer 244, the first top electrode 246, the decoupling layer 260, the second bottom electrode 272, the second piezoelectric layer 274, the second top electrode 276 or the second passivation layer 250 is formed.

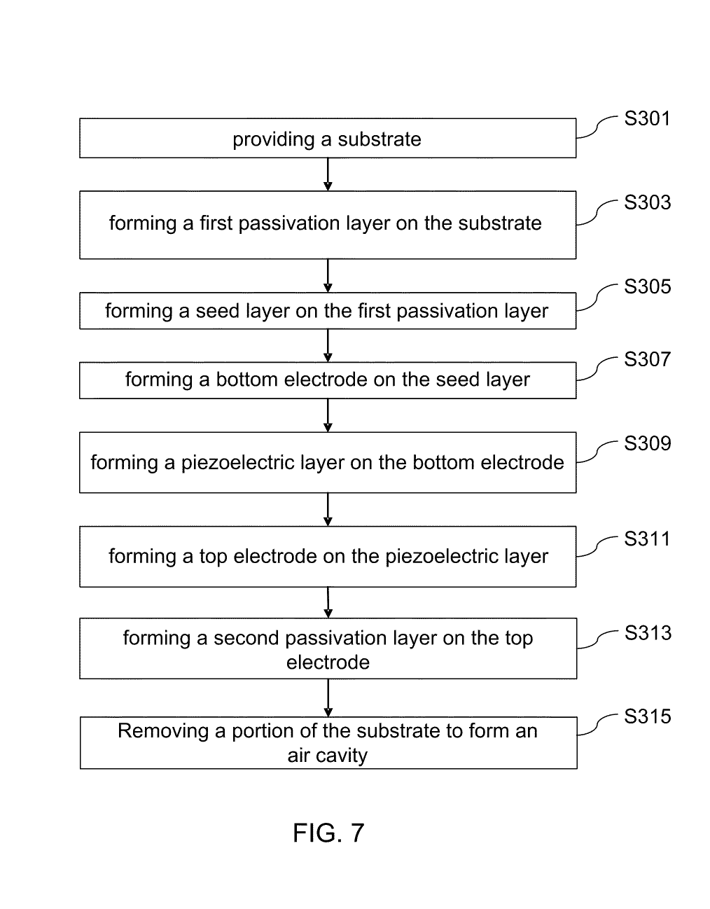

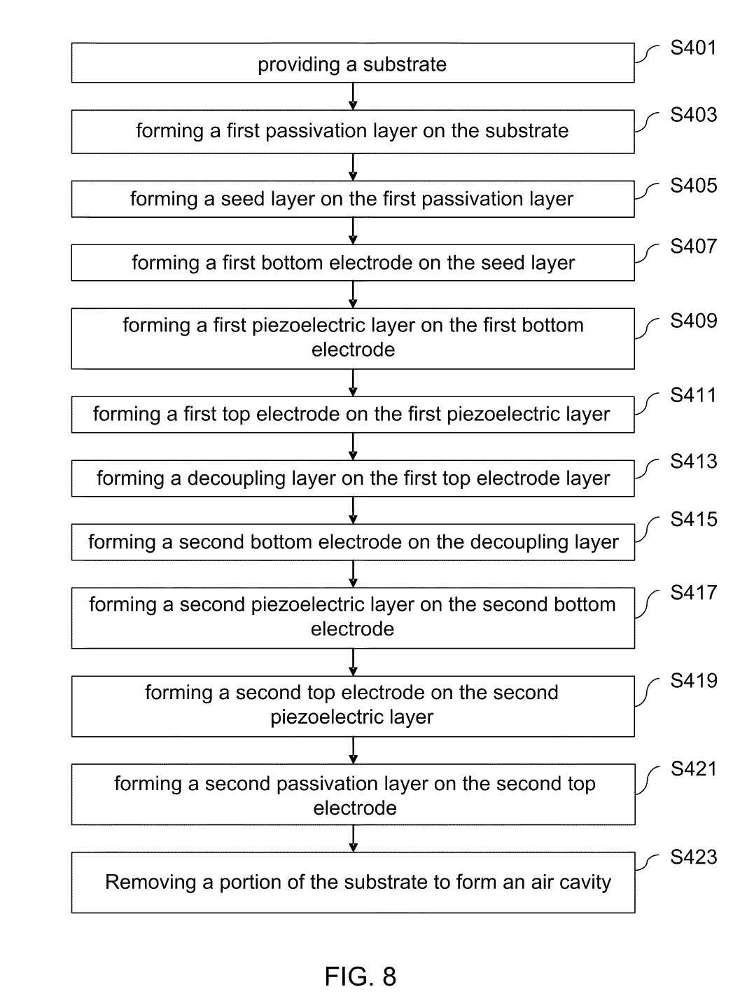

Referring to FIG. 7, accompanying with FIGS. 3A and 3B, a manufacturing flowchart of an acoustic wave resonator is shown according to yet another embodiment of the present invention. The manufacturing process includes the following steps.

At step S301, a substrate 310 is provided.

At step S303, a first passivation layer 320 is formed on the substrate 310.

At step S305, a seed layer 330 is formed on the first passivation layer 320. Typically, the seed layer 330 is sputtered on the surface of the first passivation layer 320.

At step S307, a bottom electrode 342 is formed on the seed layer 330.

At step S309, a piezoelectric layer 344 is formed on the bottom electrode 342.

At step S311, a top electrode 346 is formed on the piezoelectric layer 344.

At step S313, a second passivation layer 350 is formed on the top electrode 346.

At step S315, a portion of the substrate 310 on which the first passivation layer 320 is formed is removed by an etching process from the backside of the substrate 310 to form an air cavity 312 therein.

Referring to FIG. 8, accompanying with FIG. 4, a manufacturing flowchart of an acoustic wave resonator is shown according to a further embodiment of the present invention. The manufacturing process includes the following steps.

At step S401, a substrate 410 is provided.

At step S403, a first passivation layer 420 is formed on the substrate 410.

At step S405, a seed layer 430 is formed on the first passivation layer 420. Typically, the seed layer 430 is sputtered on the surface of the first passivation layer 420.

At step S407, a first bottom electrode 442 is formed on the seed layer 430.

At step S409, a first piezoelectric layer 444 is formed on the first bottom electrode 442.

At step S411, a first top electrode 446 is formed on the first piezoelectric layer 444.

At step S413, a decoupling layer 460 is formed on first top electrode 446.

At step S415, a second bottom electrode 472 is formed on the decoupling layer 460.

At step S417, a second piezoelectric layer 474 is formed on the second bottom electrode 472.

At step S419, a second top electrode 476 is formed on the second piezoelectric layer 474.

At step S421, a second passivation layer 450 is formed on the second top electrode 446.

At step S423, a portion of the substrate 410 on which the first passivation layer 420 is formed is removed by an etching process from the backside of the substrate 410 to form an air cavity 412 therein.

In summary, the present invention, among other things, recites an acoustic wave resonator having at least one passivation layer. The passivation layer is adapted for reducing the tendency of a material absorbed on the surface of the resonator structure and serves as a protective underlayer protecting the seed layer from reaction with air and possible moisture from the environment reaching the seed layer via an air cavity, which is a hole left after the sacrificial layer released. Accordingly, the resonant frequency drifting caused by environment contaminants is minimized and the resonator is protected from detrimental effects caused by humidity or corrosive fluids.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An acoustic wave resonator, comprising:
(a) a substrate defining an air cavity;
(b) a first passivation layer formed on the substrate and located over the air cavity;
(c) a seed layer formed on the first passivation layer such that the first passivation layer protects the seed layer from reaction with an environment surrounding the resonator;
(d) a multilayered structure formed on the seed layer; and
(e) a second passivation layer formed on the top surface of the multilayered structure.

2. The acoustic wave resonator of claim 1, wherein the multilayered structure comprises:
(a) a bottom electrode formed on the seed layer;
(b) a piezoelectric layer formed on the bottom electrode; and
(c) a top electrode formed on the piezoelectric layer.

3. The acoustic wave resonator of claim 1, wherein the multilayered structure comprises:
(a) a first bottom electrode formed on the seed layer;
(b) a first piezoelectric layer formed on the first bottom electrode;
(c) a first top electrode formed on the first piezoelectric layer;
(d) a decoupling layer formed on the first top electrode;
(e) a second bottom electrode formed on the decoupling layer;
(f) a second piezoelectric layer formed on the second bottom electrode; and
(g) a second top electrode formed on the second piezoelectric layer.

4. The acoustic wave resonator of claim 1, wherein the first passivation layer comprises a material of silicon carbide, aluminum oxide, diamond, diamond-like carbon (DLC), silicon oxide, silicon nitride, hydrophobic polymer or a combination thereof.

5. The acoustic wave resonator of claim 2, wherein the second passivation layer comprises a material that is different from or identical to the material of the first passivation layer.

6. The acoustic wave resonator of claim 1, wherein the first passivation layer has a thickness ranging from 10 Angstroms to 10,000 Angstroms.

7. The acoustic wave resonator of claim 1, wherein the seed layer comprises a material of aluminum nitride, aluminum oxynitride, tungsten nitride, titanium tungsten nitride, silicon oxide, silicon nitride, silicon carbide, or a combination thereof.

8. A method for manufacturing an acoustic wave resonator, comprising the steps of:
(a) providing a substrate with a sacrificial layer;
(b) forming a first passivation layer on the sacrificial layer extending over the substrate layer;
(c) forming a seed layer on the first passivation layer;
(d) forming a multilayered structure;
(e) forming a second passivation layer on the top surface of the multilayered structure; and
(f) removing the sacrificial layer from the substrate to form an air cavity.

9. The method of claim 8, wherein the step of forming the multilayered structure multilayered structure comprises the steps of:
(a) forming a bottom electrode on the seed layer;
(b) forming a piezoelectric layer on the bottom electrode; and
(c) forming a top electrode on the piezoelectric layer.

10. The method of claim 8, wherein the step of forming the multilayered structure multilayered structure comprises the steps of:
(a) forming a first bottom electrode on the seed layer;
(b) forming a first piezoelectric layer on the first bottom electrode;
(c) forming a first top electrode on the first piezoelectric layer;
(d) forming a decoupling layer on the first top electrode;
(e) forming a second bottom electrode on the decoupling layer;
(f) forming a second piezoelectric layer on the second bottom electrode; and
(g) forming a second top electrode on the second piezoelectric layer.

11. The method of claim 8, wherein the first passivation layer is formed of a material of silicon carbide, aluminum oxide, diamond, diamond-like carbon (DLC), silicon oxide, silicon nitride, hydrophobic polymer and a combination thereof.

12. The method of claim 8, wherein the second passivation layer is formed of a material that is different from or identical to the material of the first passivation layer.

13. The method of claim 8, wherein the first passivation layer has a thickness ranging from 10 Angstroms to 10,000 Angstroms.

14. The method of claim 8, wherein the seed layer is formed of a material of aluminum nitride, aluminum oxynitride, tungsten nitride, titanium tungsten nitride, silicon oxide, silicon nitride, silicon carbide, or a combination thereof.

15. A method for manufacturing an acoustic wave resonator, comprising the steps of:
(a) providing a substrate;
(b) forming a first passivation layer on the substrate;
(c) forming a seed layer on the first passivation layer;
(d) forming a multilayered structure;
(e) forming a second passivation layer on the top surface of the multilayered structure; and
(f) removing a portion of the substrate on which the first passivation layer is formed to form an air cavity therein.

16. The method of claim 15, wherein the step of forming the multilayered structure multilayered structure comprises the steps of:
(a) forming a bottom electrode on the seed layer;
(b) forming a piezoelectric layer on the bottom electrode; and
(c) forming a top electrode on the piezoelectric layer.

17. The method of claim 15, wherein the step of forming the multilayered structure multilayered structure comprises the steps of:
(a) forming a first bottom electrode on the seed layer;
(b) forming a first piezoelectric layer on the first bottom electrode;
(c) forming a first top electrode on the first piezoelectric layer.
(d) forming a decoupling layer on the first top electrode;
(e) forming a second bottom electrode on the decoupling layer;
(f) forming a second piezoelectric layer on the second bottom electrode; and
(g) forming a second top electrode on the second piezoelectric layer.

18. The method of claim 15, wherein the first passivation layer is formed of a material of silicon carbide, aluminum oxide, diamond, diamond-like carbon (DLC), silicon oxide, silicon nitride, hydrophobic polymer and a combination thereof.

19. The method of claim 15, wherein the second passivation layer is formed of a material that is different from or identical to the material of the first passivation layer.

20. The method of claim 15, wherein the first passivation layer has a thickness ranging from 10 Angstroms to 10,000 Angstroms.

21. The method of claim 15, wherein the seed layer is formed of a material of aluminum nitride, aluminum oxynitride, tungsten nitride, titanium tungsten nitride, silicon oxide, silicon nitride, silicon carbide, or a combination thereof.

22. An acoustic wave resonator, comprising:
(a) a substrate having a first surface and an opposite second surface, and defining an air cavity on the first surface;
(b) a first passivation layer formed on the first surface of the substrate and positioned over the air cavity;
(c) a second passivation layer positioned apart from the first passivation layer; and
(d) a multilayered structure formed between the first passivation layer and the second passivation layer.

23. The acoustic wave resonator of claim 22, further comprising a seed layer formed between the first passivation layer and the multilayered structure such that the first passivation layer protects the seed layer from reaction with an environment surrounding the resonator.
